(19) United States
(12) Patent Application Publication
(10) Pub. No.: US 2010/0133613 A1
(43) Pub. Date: Jun. 3, 2010

(54) SEMICONDUCTOR MEMORY DEVICE AND MANUFACTURING METHOD THEREOF

(75) Inventor: Hironobu FURUHASHI, Yokohama-Shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/564,522

(22) Filed: Sep. 22, 2009

(30) Foreign Application Priority Data
Nov. 28, 2008 (JP) 2008-303907

(51) Int. Cl. H01L 29/78; H01L 21/84

(52) U.S. Cl. 257/347; 438/151; 257/E29.255; 257/E21.409

(57) ABSTRACT

A semiconductor memory device includes a supporting substrate; an insulation film provided on the supporting substrate; a source layer provided on the insulation film; a drain layer provided on the insulation film; a body region provided between the source layer and the drain layer and being in an electrically floating state, the body region accumulating electric charges or discharging electric charges in order to store data; a boundary gate dielectric film provided at least on a boundary portion between the body region and the source layer and on a boundary portion between the body region and the drain layer; and a center gate dielectric film provided adjacently to the boundary gate dielectric film on the body region, the center gate dielectric film having more interface states than the boundary gate dielectric film has.

### CROSS-REFERENCE TO RELATED APPLICATION

This application is based upon and claims the benefit of priority from the prior Japanese Patent Applications No. 2008-303907, filed on Nov. 28, 2008, the entire contents of which are incorporated herein by reference.

### BACKGROUND OF THE INVENTION

1. Field of the Invention

The present invention relates to a semiconductor memory device and manufacturing method thereof.

2. Related Art

In recent years, FBC (Floating Body Cell) memory devices are available as semiconductor memory devices expected as memories alternative to 1T (Transistor)-1C (Capacitor) DRAMs. An FBC memory device has an FET (Field Effect Transistor) including a floating body (hereinafter, also “body”) formed on an SOI (Silicon On Insulator) substrate. The FBC memory device stores data “1” or “0” depending on the number of majority carriers accumulated in the body. For example, in an FBC including an N-FET, a state of a large number of holes accumulated in the body is set as data “1”, and a state of a small number of holes is set as data “0”. Memory cells storing the data “0” are called “0” cells, and memory cells storing the data “1” are called “1” cells.

As a disturbance to “1” cells, there has been known a “charge pumping phenomenon”. The charge pumping phenomenon is a phenomenon in which holes accumulated in non-selected memory cells at reading/writing times are recombined with electrons trapped by interface states within a gate dielectric film. When the charge pumping phenomenon is repeated, there is a risk that the state of the data “1” in the non-selected memory cells is changed to the data “0”. Therefore, generally, the charge pumping phenomenon is recognized as a disturbance to the “1” cells.

Further, the interface states of the gate dielectric film degrade the gate dielectric film at a boundary portion between the body and a drain or at a boundary portion between the body and a source.

Therefore, in order to suppress the disturbance to the “1” cells, efforts are conventionally made to decrease interface states within a gate dielectric film of memory cells.

### SUMMARY OF THE INVENTION

A semiconductor memory device according to an embodiment of the present invention comprises: a supporting substrate; an insulation film provided on the supporting substrate; a source layer provided on the insulation film; a drain layer provided on the insulation film; a body region provided between the source layer and the drain layer and being in an electrically floating state, the body region accumulating electric charges or discharging electric charges in order to store data; a boundary gate dielectric film provided at least on a boundary portion between the body region and the source layer and on a boundary portion between the body region and the drain layer; and a center gate dielectric film provided adjacently to the boundary gate dielectric film on the body region, the center gate dielectric film having more interface states than the boundary gate dielectric film has.

A semiconductor memory device according to an embodiment of the present invention comprises: a supporting substrate; an insulation film provided on the supporting substrate; a source layer provided on the insulation film; a drain layer provided on the insulation film; a body region provided between the source layer and the drain layer and being in an electrically floating state, the body region accumulating electric charges or discharging electric charges in order to store data; a boundary gate dielectric film provided at least on a boundary portion between the body region and the source layer and on a boundary portion between the body region and the drain layer, the boundary gate dielectric film having an interface state density lower than 10¹¹eV⁻¹cm⁻²; and a center gate dielectric film provided adjacently to the boundary gate dielectric film on the body region, the center gate dielectric film having an interface state density equal to or higher than 10¹¹eV⁻¹cm⁻².

A method of manufacturing a semiconductor memory device according to an embodiment of the present invention comprising as memory cells a plurality of FETs comprising a body region provided between a source layer and a drain layer and in an electrically floating state to accumulate electric charges or to discharge electric charges in order to store data, the method comprises: forming a center gate dielectric film on a semiconductor layer provided on an insulation film; forming first gate electrodes on the center gate dielectric film; etching a side surface of the first gate electrodes in order to narrow a width of the first gate electrodes in a channel length direction of the memory cells; etching the center gate dielectric film by using the first gate electrodes as a mask; forming a boundary gate dielectric film on the semiconductor layer exposed; forming second gate electrodes on a side wall of the first gate electrodes; and forming the source layer and the drain layer by introducing an impurity into the semiconductor layer by using the first gate electrodes and the second gate electrodes as a mask, wherein the boundary gate dielectric film is on a boundary portion between the body region and the source layer and on a boundary portion between the body region and the drain layer, and the center gate dielectric film is provided adjacently to the boundary gate dielectric film on the body region.

A method of manufacturing a semiconductor memory device according to an embodiment of the present invention comprising as memory cells a plurality of FETs comprising a body region provided between a source layer and a drain layer and in an electrically floating state to accumulate electric charges or to discharge electric charges in order to store data, the method comprises: forming a boundary gate dielectric film on a semiconductor layer provided on an insulation film; forming a mask material on the boundary gate dielectric film; removing a part of the mask material on a forming region of a gate electrode of the FET to expose the boundary gate dielectric film; forming first gate electrodes on side surfaces of the mask material in the forming region of the gate electrode; forming a center gate dielectric film by nitriding the boundary gate dielectric film using the mask material and the first gate electrodes as a mask; filling the forming region of the gate electrode of the FET with a material of a second gate electrode; removing the mask material; and forming the source layer and the drain layer by introducing an impurity into the semiconductor layer by using the first gate electrodes and the second gate electrodes as a mask, wherein the boundary gate dielectric film is on a boundary portion between the body region and the source layer and on a boundary portion between the body region and the drain layer, and the center gate dielectric film is provided adjacently to the boundary gate dielectric film on the body region.

A method of manufacturing a semiconductor memory device according to an embodiment of the present invention comprising as memory cells a plurality of FETs comprising a body region provided between a source layer and a drain layer and in an electrically floating state to accumulate electric charges in order to store data or to discharge electric charges, the method comprises: forming a center gate dielectric film on a semiconductor layer provided on an insulation film; forming gate electrodes on the center gate dielectric film; etching the center gate dielectric film by using the gate electrodes as a mask in order to narrow a width of the center gate dielectric film in a channel length direction of the FETs; forming a boundary gate dielectric film so as to be adjacent to the center gate dielectric film below the gate electrodes; and forming the source layer and the drain layer by introducing an impurity into the semiconductor layer by using the gate electrodes as a mask, wherein the boundary gate dielectric film is on a boundary portion between the body region and the source layer and on a boundary portion between the body region and the drain layer, and the center gate dielectric film is provided adjacently to the boundary gate dielectric film on the body region.

### BRIEF DESCRIPTION OF THE DRAWINGS

FIG. 1 is a partial plan view showing a configuration of an FBC memory according to a first embodiment of the present invention;

FIG. 2 is a cross-sectional view along a line 2-2 in FIG. 1;

FIG. 3 is a cross-sectional view along a line 3-3 in FIG. 1;

FIG. 4 is a graph showing a relationship between the body current Ibody and the body potential Vbody;

FIG. 5 to FIG. 16B are plan views or cross-sectional views showing a method of manufacturing the FBC memory according to the first embodiment;

FIG. 17 to FIG. 27 are plan views or cross-sectional views showing a method of manufacturing the FBC memory according to the second embodiment; and

FIG. 28 to FIG. 30 are plan views or cross-sectional views showing a method of manufacturing the FBC memory according to the third embodiment.

### DETAILED DESCRIPTION OF THE INVENTION

Embodiments of the present invention will be explained below in detail with reference to the accompanying drawings. Note that the invention is not limited thereto.

### First Embodiment

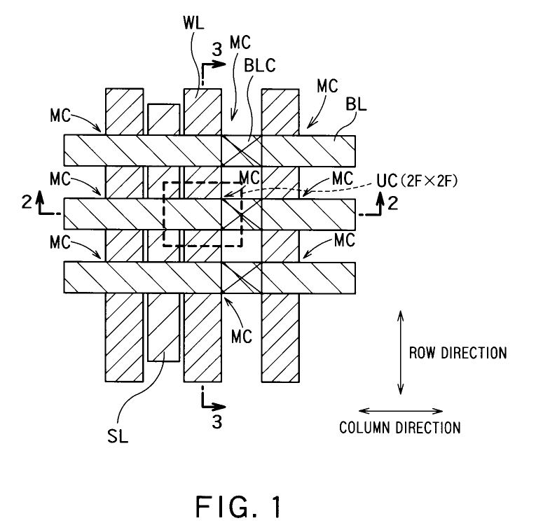

FIG. 1 is a partial plan view showing a configuration of an FBC memory according to a first embodiment of the present invention. Memory cells MC are arranged in a matrix shape, thereby constituting a memory cell array MCA. Word lines WL are extended to a row direction, and are connected to gates of the memory cells MC. Bit lines BL are extended to a column direction, and are connected to drains of the memory cells MC. The word lines WL and the bit lines BL are orthogonal to each other, and the memory cells MC are provided at respective intersections. These cells are called cross-point cells.

In the first embodiment, source lines SL are extended to a row direction in a similar manner to that of the word lines WL, and are connected to sources of the memory cells MC. One source line SL is provided commonly to two word lines WL. That is, memory cells MC connected to adjacent two word lines WL share the source line SL. The bit lines BL are connected to drains of the memory cells MC, and are provided corresponding to arrangement of each column of each memory cell MC. However, drains of two memory cells MC adjacent in an extension direction (a column direction) of the bit lines BL are shared by the two memory cells MC. That is, drains of two memory cells MC adjacent in a column direction are commonly connected to one bit line contact BLC.

Addressing terms of the row direction and the column direction are given only for descriptive conveniences, and thus these can be mutually replaced.

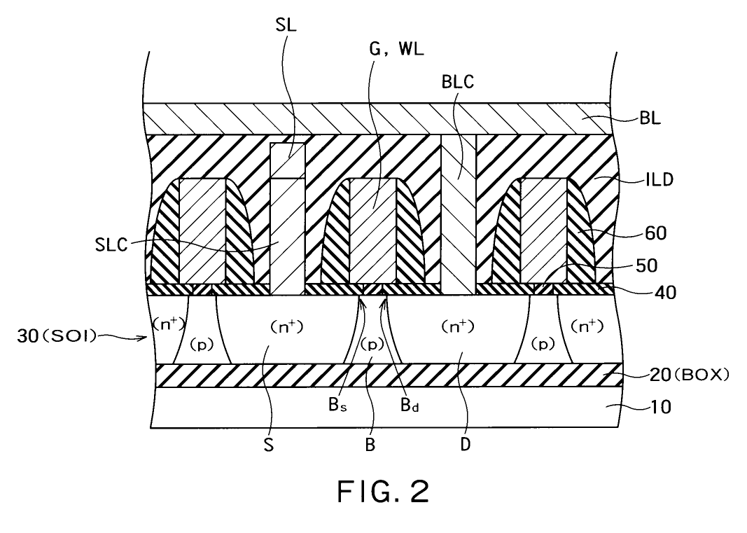

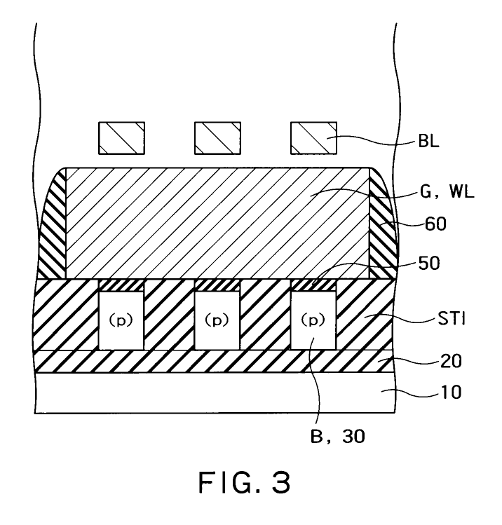

FIG. 2 is a cross-sectional view along a line 2-2 in FIG. 1. FIG. 3 is a cross-sectional view along a line 3-3 in FIG. 1. The memory cells MC are provided on an SOI substrate including a silicon substrate 10, a BOX (Buried Oxide) layer 20, and a p-type SOI layer 30. The memory cells MC have a configuration of a MISFET (Metal Insulator Semiconductor Field Effect Transistor). The SOI layer 30 is formed in a stripe shape, and constitutes an active area. An STI (Shallow Trench Isolation) is embedded in between active areas as shown in FIG. 3. A certain potential is applied to the silicon substrate 10 via a plug (not shown).

An n⁺ source S and an n⁺ drain D are provided within the SOI layer 30 on the BOX layer 20. A body B is formed in the SOI layer 30 between the source S and the drain D. The body B includes a semiconductor having conductivity opposite to that of the source S and the drain D, and is in an electrically floating state. In the first embodiment, the memory cells MC are N-FETs. A part or a whole of the body B is surrounded by the source S, the drain D, the BOX layer 20, a boundary gate dielectric film 40, a center gate dielectric film 50, and the STI, in such a manner that the body B is in an electrically floating state. The body B accumulates majority carriers (holes) in order to store data, or discharges majority carriers. The FBC memory can store logic data (binary data) depending on the number of majority carriers within the body B.

The source S and the drain D can include n⁻ extension layers formed around an n⁺ diffusion layer of high impurity concentration.

A gate dielectric film of one memory cell MC includes the boundary gate dielectric film 40 and the center gate dielectric film 50. The boundary gate dielectric film 40 is provided on at least a boundary portion Bs between the body B and the source S and on a boundary portion Bd between the body B and the drain D. In the first embodiment, a gate dielectric film other than a center portion of a channel of each memory cell MC is the boundary gate dielectric film 40. The center gate dielectric film 50 is provided adjacently to the boundary gate dielectric film 40 on the body B, and is positioned at the center of the channel of the memory cell MC. The center gate dielectric film 50 is not provided on the boundary portions Bs and Bd.

The center gate dielectric film 50 is formed by a material having more interface states than those of a material of the boundary gate dielectric film 40. The center gate dielectric film 50 is an insulation film having Dit (interface state density) equal to or higher than 10¹¹eV⁻¹cm⁻². Specifically, the center gate dielectric film 50 includes a silicon nitride film, an HfSiON film, an LP (Low Pressure)-TEOS film, or a stacked film (an NO film) of a silicon nitride film and a silicon oxide film. Other insulation films can be stacked on the center gate dielectric film 50.

The boundary gate dielectric film 40 is an insulation film having Dit lower than 10¹¹eV⁻¹cm⁻². Specifically, the boundary gate dielectric film 40 is a silicon thermally-oxidized film. Other insulation films can be stacked on the boundary gate dielectric film 40. Dit changes depending on a formation method of an insulation film. Therefore, materials of the center gate dielectric film 50 and the boundary gate dielectric film 40 are not limited to the above materials.

A gate electrode G is formed on the boundary gate dielectric film 40 and the center gate dielectric film 50. The gate electrode G is continuously extended to a row direction, and functions as a word line WL, as shown in FIG. 3. A sidewall film 60 is formed on a side surface of the word line WL. The word line WL and the sidewall film 60 are covered by an interlayer dielectric film ILD.

A source line contact SLC is provided within the interlayer dielectric film ILD in order to connect between the source line SL and the source S. A bit line contact BLC is provided within the interlayer dielectric film ILD in order to connect between the bit line BL and the drain D. The source line contact SLC is connected to the source S common to two memory cells MC adjacent in a column direction. The bit line contact BLC is connected to the drain D common to two memory cells MC adjacent in a column direction. The source line contact SLC and the bit line contact BLC are alternately provided in a column direction.

The boundary gate dielectric film 40 provided in offset regions between the gate electrode G and the source/drain diffusion layers (a region from the boundary portion Bs to an end of the gate G, and a region from the boundary portion Bd to the end of the gate G) has a smaller number of interface states than that of interface states of the center gate dielectric film 50. Therefore, deterioration of the gate dielectric film by hot carriers generated by impact ionization at a writing time of the data “1” can be suppressed. Consequently, the life of the gate dielectric film can be maintained. In addition, a gate dielectric film at the center of the channel is formed by the center gate dielectric film 50 having more interface states than those of the boundary gate dielectric film 40. Therefore, the FBC memory according to the first embodiment can efficiently generate a charge pumping phenomenon.

As described above, generally, a charge pumping phenomenon is considered as an undesirable phenomenon generating a disturbance to the “1” cells. On the other hand, the charge pumping phenomenon can be effectively utilized in order to exclude holes from the “0” cells.

According to an automatic refresh of the first embodiment, a charge pumping phenomenon occurs in both the “1” cells and the “0” cells. The charge pumping phenomenon can restore a body potential of the “0” cells. On the other hand, while the charge pumping phenomenon decreases holes of the “1” cells, many holes are accumulated in the “1” cells due to impact ionization. Therefore, the charge pumping phenomenon at this time is not so much influenced by the body potentials of the “1” cells.

A refresh operation according to the first embodiment is explained below. In the first embodiment, both the “1” cells and the “0” cells present in the same column can be refreshed at the same time by performing an autonomous refresh. The refresh operation is an operation of restoring data of the “0” cells and the “1” cells from degraded data. In the first embodiment, this operation is a replenishment of holes into the body B of the “1” cells and an extraction of holes from the body B of the “0” cells. By performing the refresh operation, a signal difference between the data “1” and the data “0” can be restored to substantially the same level as that at the data writing time.

The autonomous refresh is an operation of simultaneously and autonomously refreshing both the “0” cells and the “1” cells by applying the same optimum word line potential VWL and the same optimum bit line potential VBL to both the “0” cells and the “1” cells without reading data. In the autonomous refresh according to the first embodiment, an impact ionization current is passed to the “1” cells, and a charge pumping phenomenon is generated in the “0” cells and the “1” cells. The impact ionization is generated in the “1” cells by a difference between a body potential of the “1” cells and a body potential of the “0” cells, and is little generated in the “0” cells. Therefore, many holes are accumulated in the body B of the “1” cells, and the number of holes within the body B of the “0” remains almost the same. The charge pumping phenomenon occurs in both the “0” cells and the “1” cells. However, many holes are already accumulated in the body B of the “1” cells. Therefore, the number of holes extinguished due to the charge pumping phenomenon does not give a large influence to the body potential of the “1” cells. Meanwhile, the number of holes degrading the data of the “0” cells is not so large. Therefore, the charge pumping phenomenon can restore the body potential of the “0” cells.

The charge pumping phenomenon can be realized by applying a voltage higher than a threshold voltage of the memory cell MC to the gate electrode G, and thereafter by applying a voltage lower than the threshold voltage to the gate electrode G. When a voltage higher than the threshold voltage is applied to the gate electrode G, a silicon interface (channel) immediately below the gate electrode G forms an inverted layer. At this time, electrons are trapped by the interface states of the center gate dielectric film 50. When a voltage lower than the threshold voltage is applied to the gate electrode G, the channel becomes an accumulation state. At this time, excess majority carriers in the body B of the “0” cells are recombined with the electrons trapped by the interface states of the center gate dielectric film 50. As a result, holes in the body B of the “0” cells can be decreased.

As described above, generally, because the charge pumping phenomenon is considered as a phenomenon undesirable for memories, efforts are conventionally made to decrease the interface states within the gate dielectric film. However, in the first embodiment, because a charge pumping phenomenon is used for the autonomous refresh of the “0” cells, the center gate dielectric film 50 preferably has more interface states. On the other hand, when many interface states are present, the gate dielectric film is easily degraded. Therefore, the boundary gate dielectric film 40 having a small number of interface states is used for the gate dielectric film that is easily influenced by hot carriers in the offset regions between the gate electrode G and the source/drain diffusion layers. With this arrangement, the FBC memory in the first embodiment has high reliability and can effectively use the charge pumping phenomenon.

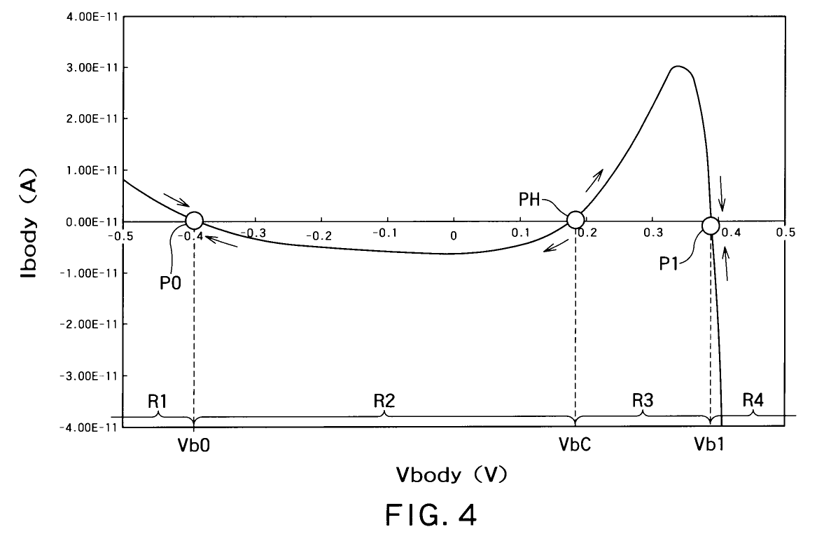

When a current flowing to the body B at the refresh time is expressed as a body current Ibody and also when a voltage of the body B is expressed as a body potential Vbody, a relationship between the body current Ibody and the body potential Vbody is expressed as shown in FIG. 4. The body current Ibody and the body potential Vbody have two stable stationary states P0 and P1 and one unstable stationary state PH. The unstable stationary state PH is positioned between the two stable stationary states P0 and P1.

Assume that a region where a body potential is equal to or lower than Vb0 is called a first region R1, that a region where a body potential is between Vb0 and Vbc is called a second region R2, that a region where a body potential is between Vbc and Vb1 is called a third region R3, and that a region where a body potential is equal to or higher than Vb1 is called a fourth region R4. The first to fourth regions R1 to R4 satisfy the following equations 1 to 4, respectively.

Ibody>0 (Vbody<Vb0) (Equation 1)

Ibody<0 (Vb0<Vbody<Vbc) (Equation 2)

Ibody>0 (Vbc<Vbody<Vb1) (Equation 3)

Ibody<0 (Vb1<Vbody) (Equation 4)

In the first region R1, a body potential Vbody increases, and a state of the memory cells MC approaches the stationary state P0. In the second region R2, the body potential Vbody decreases, and a state of the memory cells MC approaches the stationary state P0. In the third region R3, the body potential Vbody increases, and a state of the memory cells MC approaches the stationary state P1. In the fourth region R4, the body potential Vbody decreases, and a state of the memory cells MC approaches the stationary state P1. As explained above, when the body current Ibody is passed, the memory cells MC approach the stable stationary states P0 and P1, with the unstable point PH as a critical value. In other words, the body current autonomously adjusts the number of holes within the body B in such a manner that the body potential Vbody is converged to either Vb0 or Vb1. By this characteristic, the memory cells MC according to the first embodiment are statically maintained in a state of either of the two stable stationary states P0 and P1 at a data holding time.

When the body potential Vbody is higher than the potential Vbc of the critical value PH, the number of holes injected into the body B is larger than the number of holes discharged from the body B. When the body potential Vbody is lower than the potential Vbc of the critical value PH, the number of holes discharged from the body B is larger than the number of holes injected into the body B. Consequently, the autonomous refresh is realized as described above.

In the first embodiment, most of holes injected into the body B are generated by an impact ionization current. Most of holes discharged from the body B are discharged from the body region by a charge pumping current.

In the stationary states P1 and P0, a quantity of holes injected into the body B by the impact ionization current flowing during one cycle of an autonomous refresh operation is substantially equal to a quantity of holes discharged from the body B by a charge pumping current in the same cycle. In the autonomous refresh of the “0” cells using the charge pumping phenomenon, although a state of the “0” cells approaches the stationary state P0, the state does not completely return to the stationary state P0 in some cases. However, this problem can be solved by adjusting a frequency of performing the autonomous refresh operation.

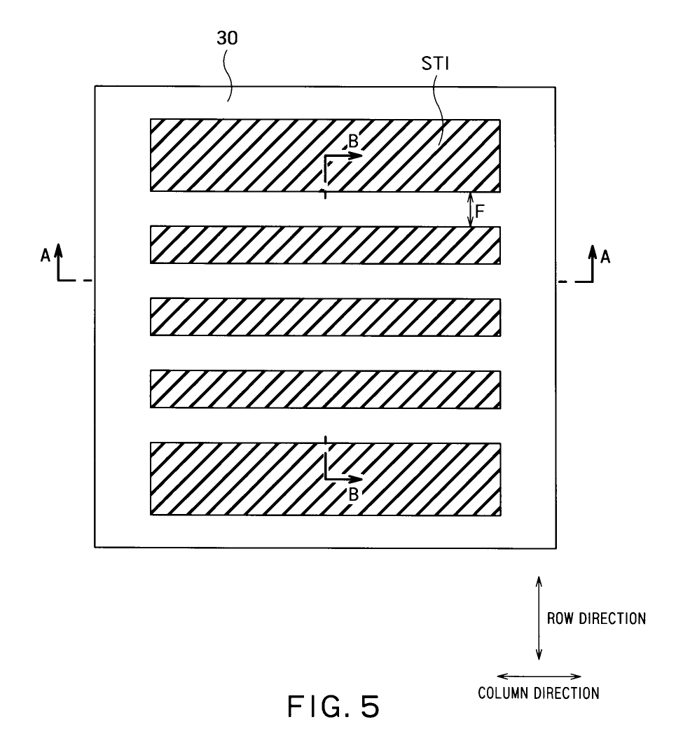

FIG. 5 to FIG. 16B are plan views or cross-sectional views showing a method of manufacturing the FBC memory according to the first embodiment.

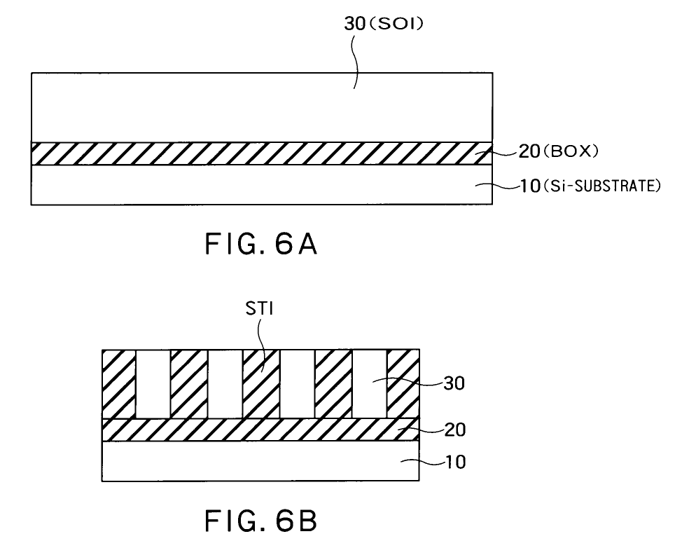

An SOI substrate is prepared first. As shown in FIG. 5, an insulation film is embedded into element isolation formation regions in the SOI layer 30, thereby forming STI. A region other than the STI in the SOI layer 30 functions as an active area. A width of the active area in a row direction is F (Feature size). F means a minimum width processable by using lithography. FIG. 6A is a cross-sectional view along a line A-A in FIG. 5. FIG. 6B is a cross-sectional view along a line B-B in FIG. 5.

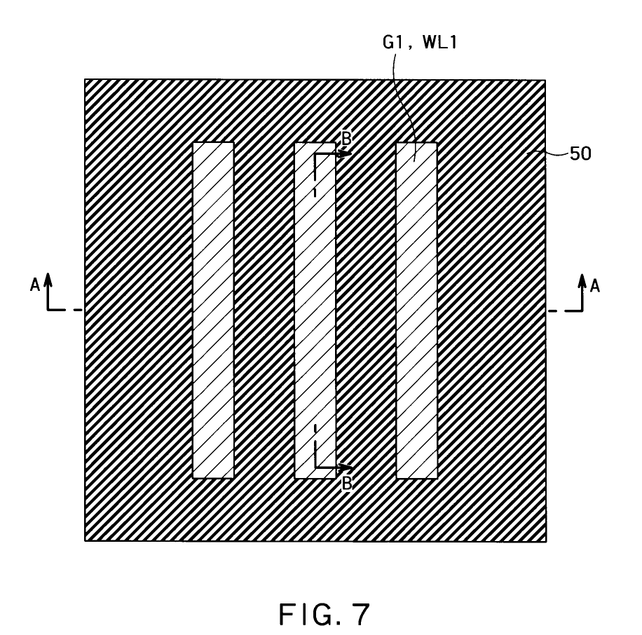

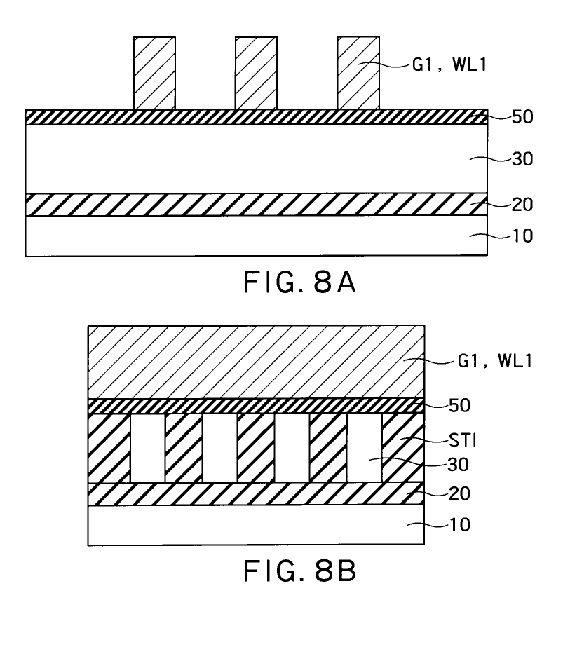

Next, as shown in FIG. 7 to FIG. 8B, a material of the center gate dielectric film 50 is formed on the SOI layer 30. In this case, the material of the center gate dielectric film 50 has many interface states. For example, the material of the center gate dielectric film 50 is an insulation film having an interface state density (Dit) equal to or higher than 10¹¹eV⁻¹cm⁻². Alternatively, the material of the center gate dielectric film 50 can be a silicon oxide film formed on the SOI layer 30 after a surface of the SOI layer 30 is roughened by nitriding. First gate electrodes G1 (word lines WL1) are then formed on the center gate dielectric film 50. An interval between the first gate electrodes G1 (WL1) adjacent in a column direction is F. FIG. 8A is a cross-sectional view along a line A-A in FIG. 7. FIG. 8B is a cross-sectional view along a line B-B in FIG. 7.

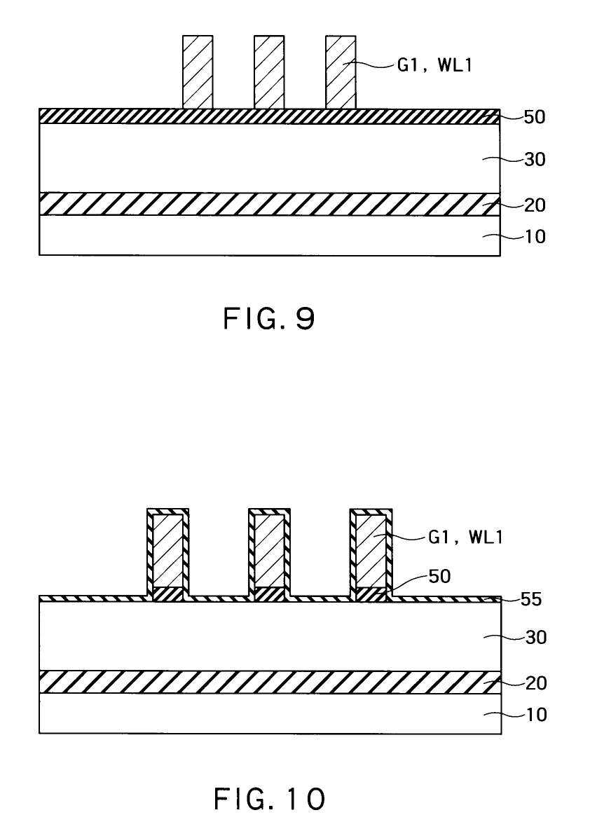

Next, as shown in FIG. 9, side surfaces of the first gate electrodes G1 (WL1) are etched to decrease a width of the first gate electrodes G1 (WL1) in a channel length direction (a column direction) of the memory cells MC. In this case, the width of the first gate electrodes G1 (WL1) in a column direction becomes a width of the center gate dielectric film 50. FIG. 9 is a cross-sectional view showing the manufacturing method following FIG. 8A.

Next, the material of the center gate dielectric film 50 is etched by using the first gate electrodes G1 (WL1) as a mask. Accordingly, a width of the first gate electrodes G1 (WL1) in a column direction is determined.

Next, as shown in FIG. 10, a cover film 55 is formed on the first gate electrodes G1 (WL1) and the SOI layer 30. The cover film 55 is provided to protect the sidewalls of the first gate electrodes G1 (WL1). Therefore, the cover film 55 can be deposited before processing the center gate dielectric film 50. In this case, the cover film 55 and the center gate dielectric film 50 are simultaneously etched by using the first gate electrodes G1 (WL1) as a mask. The cover film 55 can be formed by the same material as that of the center gate dielectric film 50. Accordingly, the cover film 55 and the center gate dielectric film 50 can be easily processed in the same process.

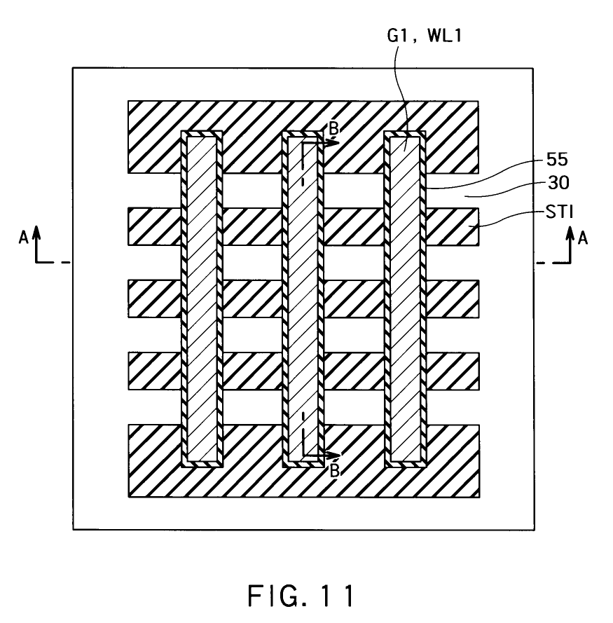

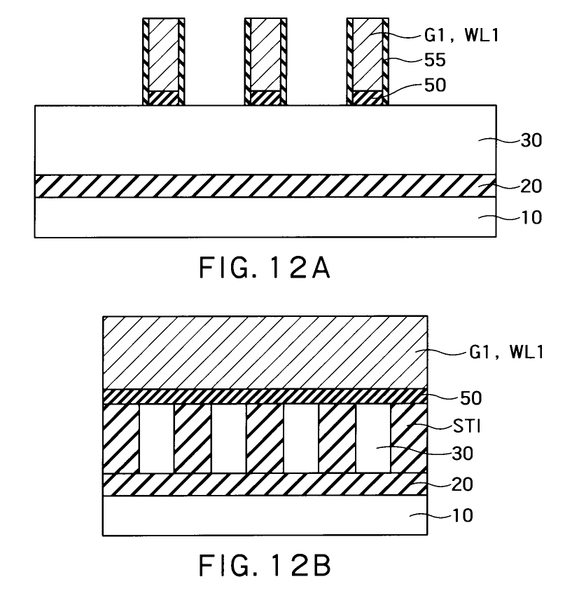

As shown in FIG. 11 to FIG. 12B, the cover film 55 is anisotropically etched. As a result, the cover film 55 is left on a sidewall of the first gate electrodes G1 (WL1).

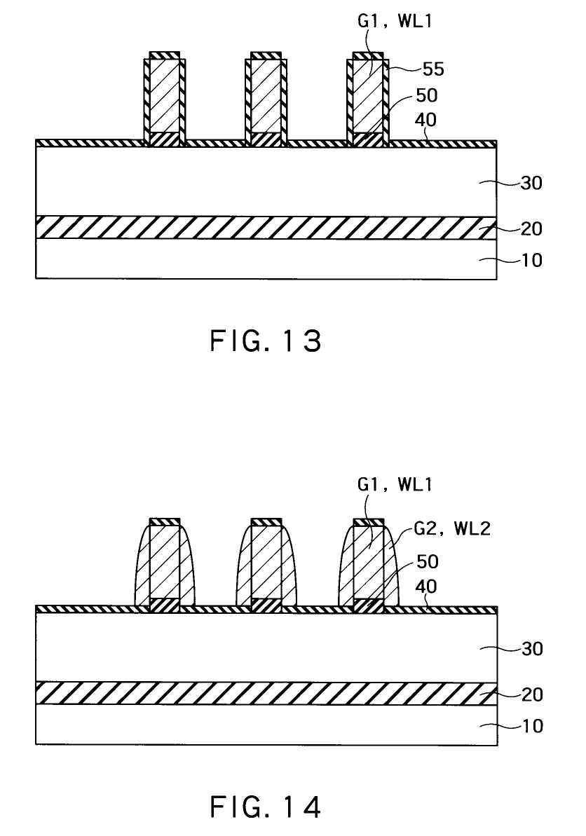

Next, as shown in FIG. 13, the cover film 55 and the center gate dielectric film 50 are removed, and thereafter, a material of the boundary gate dielectric film 40 is formed on the SOI layer 30. For example, the material of the boundary gate dielectric film 40 is an insulation film having an interface state density (Dit) lower than 10¹¹ev⁻¹cm⁻². At the time of forming the boundary gate dielectric film 40, the side surface of the first gate electrodes G1 (WL1) is in a state of being covered by the cover film 55. Therefore, the side surface of the first gate electrodes G1 (WL1) is not oxidized. FIG. 13 is a cross-sectional view showing the manufacturing method following FIG. 12A.

The cover film 55 is then removed by anisotropic etching, thereby exposing the side surface of the first gate electrodes G1 (WL1). Next, as shown in FIG. 14, second gate electrodes G2 (word lines WL2) are formed on the side surface of the first gate electrodes G1 (WL1). The first gate electrodes G1 (WL1) and the second gate electrodes G2 (WL2) are formed by the same material (polysilicon, for example). Therefore, a set of the first gate electrode G1 (WL1) and the second gate electrode G2 (WL2) functions as one word line WL as one unit. Therefore, the first gate electrodes G1 (WL1) and the second gate electrodes G2 (WL2) are hereinafter collectively called word lines WL. FIG. 14 is a cross-sectional view showing the manufacturing method following FIG. 13.

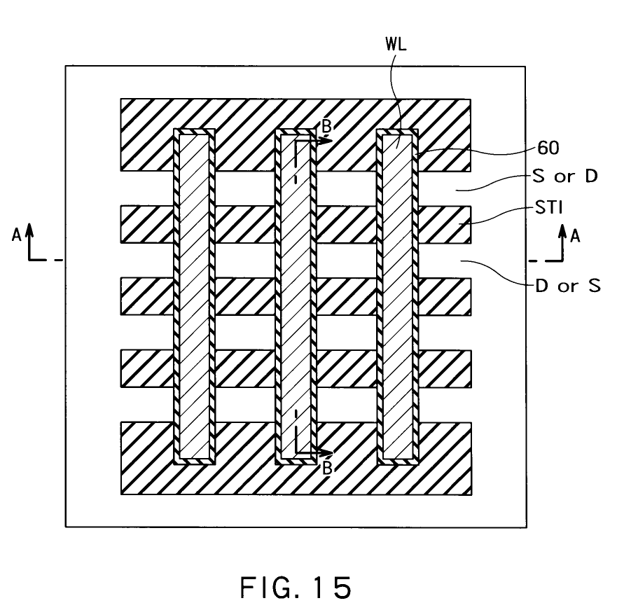

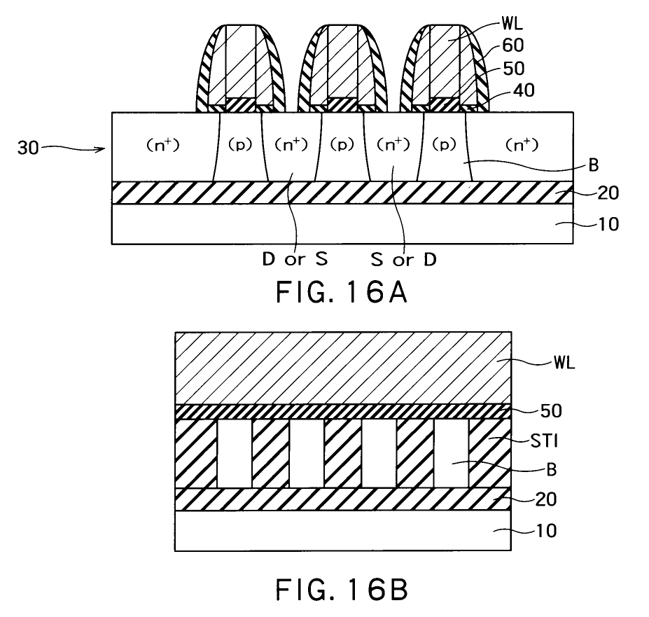

Next, as shown in FIG. 15 to FIG. 16B, the sidewall film 60 is formed on the side surface of the word lines WL. The sidewall film 60 is formed by a silicon nitride film, for example. An n-type impurity is introduced into the SOI layer 30 by using the word lines WL and the sidewall film 60 as a mask. Further, by heat processing, an n⁺ diffusion layer is formed in self alignment. This diffusion layer becomes the source S or the drain D. According to need, an n-type extension layer (not shown) can be formed around the source S or the drain D. The SOI layer 30 between the source S and the drain D becomes the body B. FIG. 16A is a cross-sectional view along a line A-A in FIG. 15. FIG. 16B is a cross-sectional view along a line B-B in FIG. 15.

The boundary gate dielectric film 40 is formed on an offset portion from an end of each word line WL to a boundary between the body and the source, and on an offset portion from an end of each word line WL to a boundary between the body and the drain. The center gate dielectric film 50 is provided adjacently to the boundary gate dielectric film 40 on the body B.

Thereafter, the interlayer dielectric film is deposited on the whole surface, and the source line contact SLC, the bit line contact BLC, the source lines SL, and the bit lines BL are formed, thereby completing the FBC memory according to the first embodiment.

According to the first embodiment, a small number of interface states are present in the gate dielectric film in the offset region at the end of the word line WL, and many interface states are present in the gate dielectric film on a center portion of the channel. With this arrangement, autonomous refresh using the charge pumping phenomenon can be efficiently performed while suppressing deterioration of reliability of the gate dielectric film due to the hot carrier.

### Second Embodiment

A second embodiment of the present invention is different from the first embodiment in a manufacturing method, while the configuration of an FBC memory according to the second embodiment can be the same as that of the first embodiment. A method of manufacturing the FBC memory according to the second embodiment is explained below.

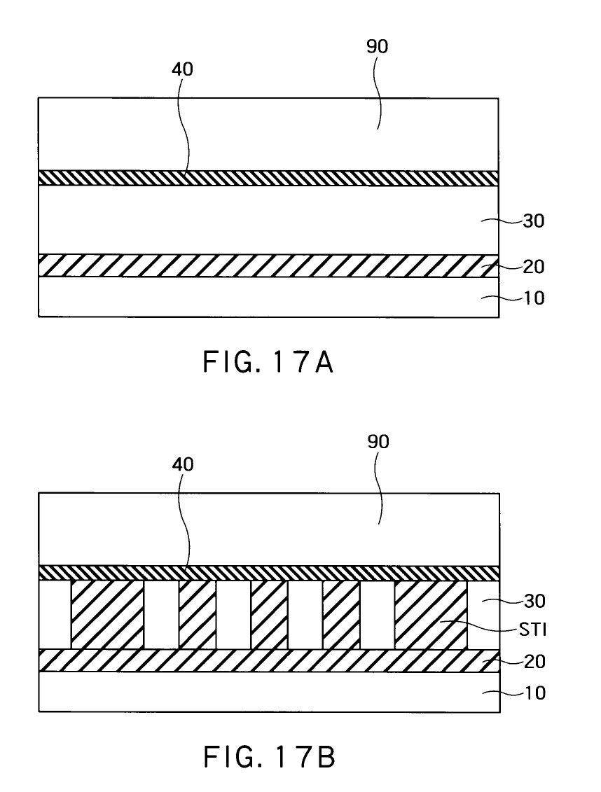

An SOI substrate is prepared in a similar manner to that of the first embodiment, thereby forming an STI. Next, as shown in FIG. 17A and FIG. 17B, a material of the boundary gate dielectric film 40 is deposited on the SOI layer 30, and a mask material 90 is deposited on the boundary gate dielectric film 40. The mask material 90 is made of a silicon nitride film, for example.

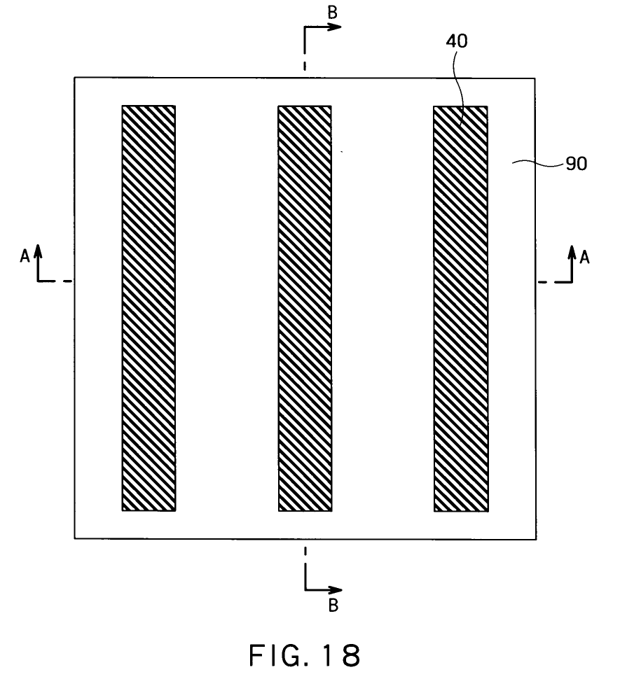

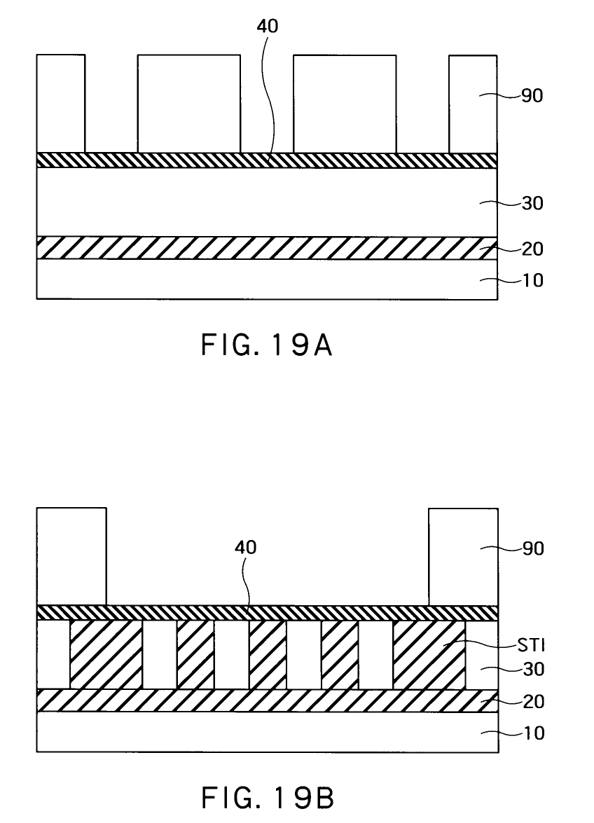

Next, as shown in FIG. 18 to FIG. 19B, the mask material 90 in formation regions of the word lines WL is removed. In this case, an upper surface of the boundary gate dielectric film 40 in the formation regions of the word lines WL is exposed. A width of the formation regions of the word line WL in a column direction is F.

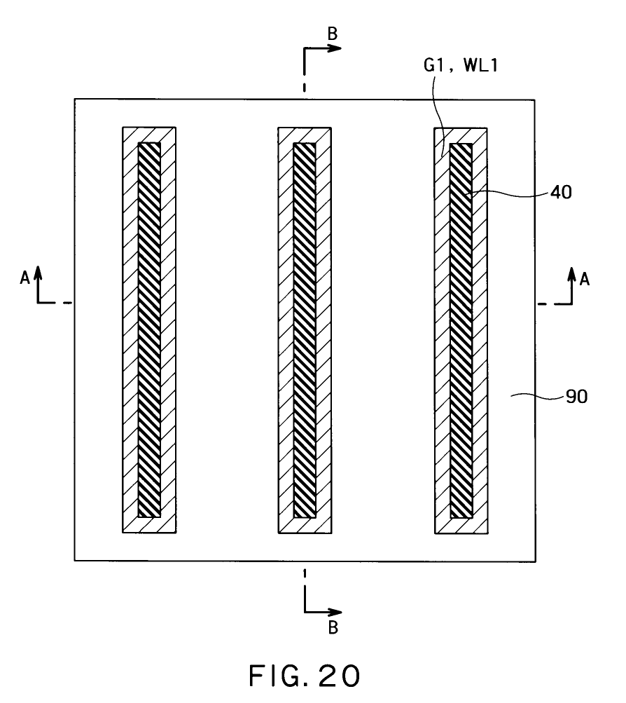

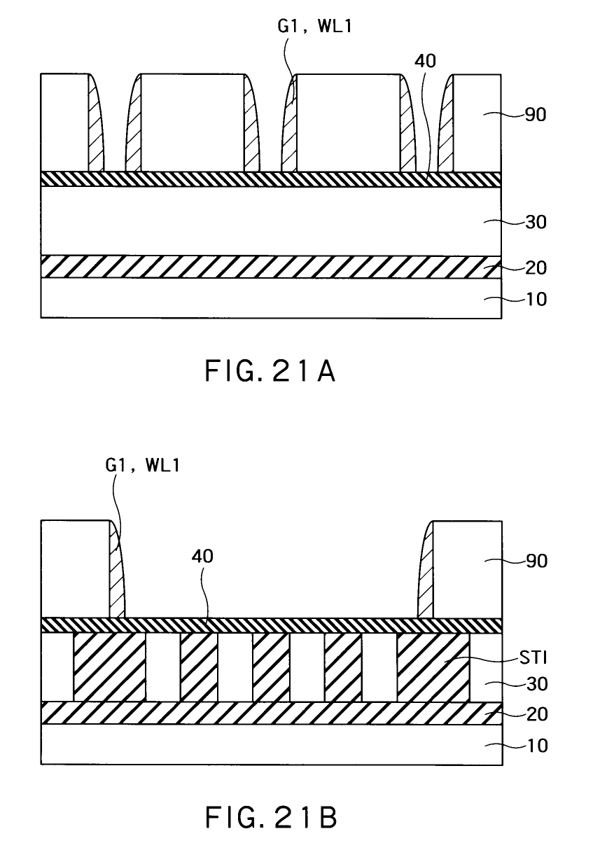

Next, as shown in FIG. 20 to FIG. 21B, the first gate electrodes G1 (word lines WL1) are formed on a side surface of the mask material 90. A width of the first gate electrodes G1 (WL1) in a column direction can be F/3, for example. FIG. 19A is a cross-sectional view along a line A-A in FIG. 18. FIG. 19B is a cross-sectional view along a line B-B in FIG. 18.

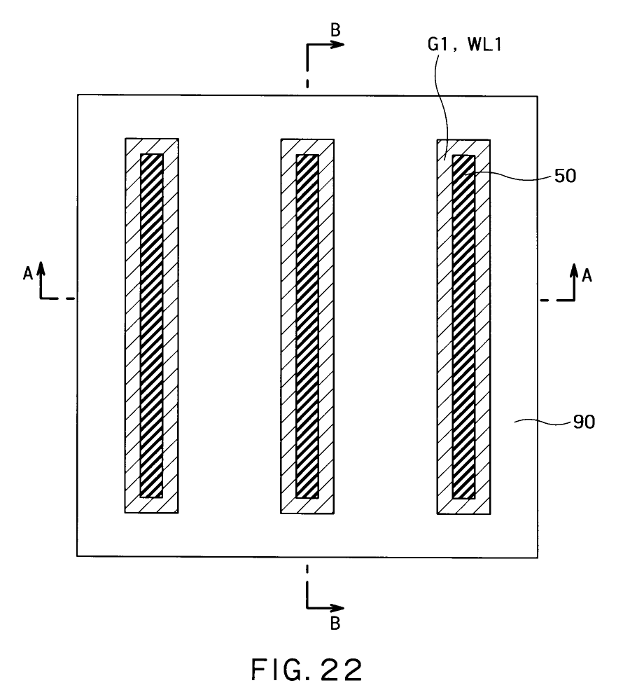

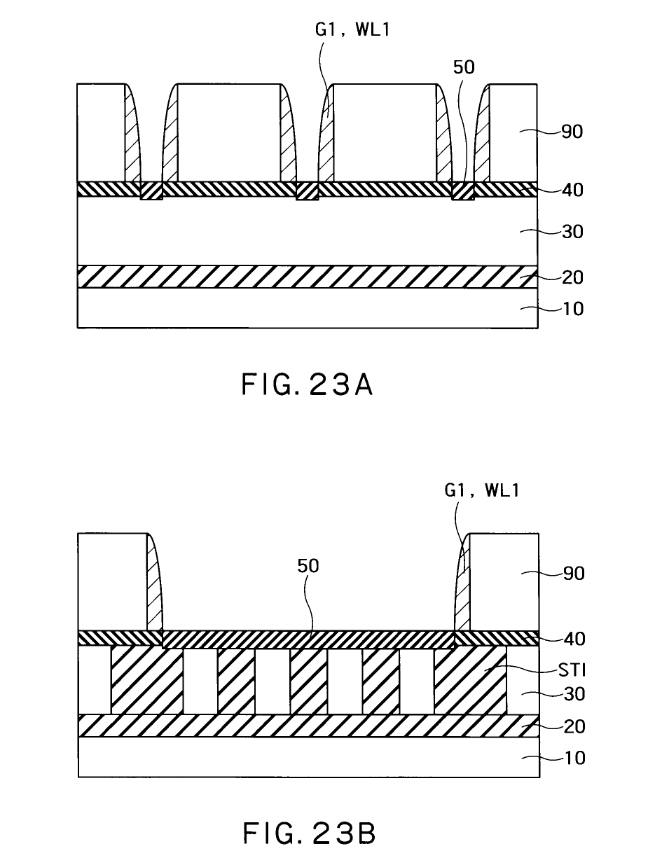

Next, as shown in FIG. 22 to FIG. 23B, the boundary gate dielectric film 40 is nitrided by using the first gate electrodes G1, WL1, and the mask material 90 as a mask. A nitrided portion of the boundary gate dielectric film 40 becomes the center gate dielectric film 50. After the nitriding, a film thickness of the center gate dielectric film 50 is adjusted by etching. In this case, a surface of the first gate electrodes G1 (WL1) has a risk of being nitrided simultaneously. However, the first gate electrodes G1 (WL1) are formed by polysilicon. Polysilicon nitride has a higher etching rate than that of a nitride film formed by monocrystalline silicon. Therefore, a nitride film formed on the first gate electrodes G1 (WL1) can be removed while keeping the center gate dielectric film 50 remaining. Alternatively, the nitride film formed on the first gate electrodes G1 (WL1) can be kept remaining. This is because the first gate electrodes and second gate electrodes can be electrically connected to each other by a contact at the later process. FIG. 23A is a cross-sectional view along a line A-A in FIG. 22. FIG. 23B is a cross-sectional view along a line B-B in FIG. 22.

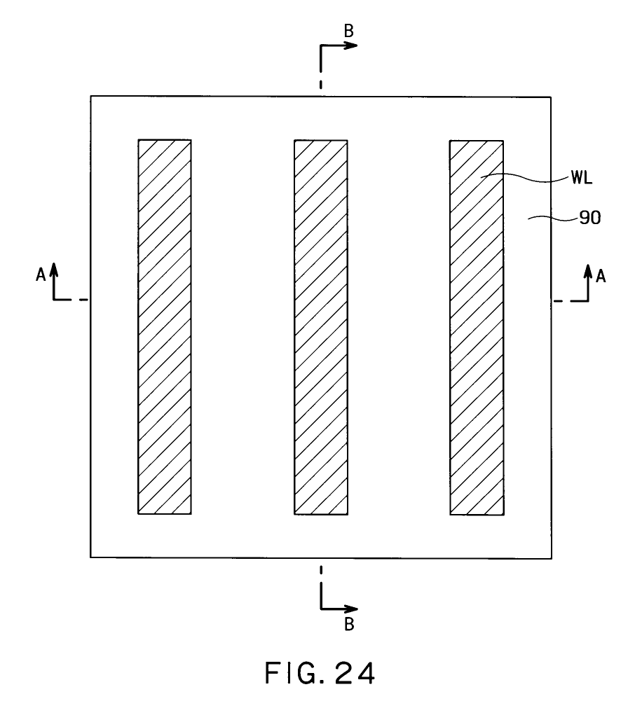

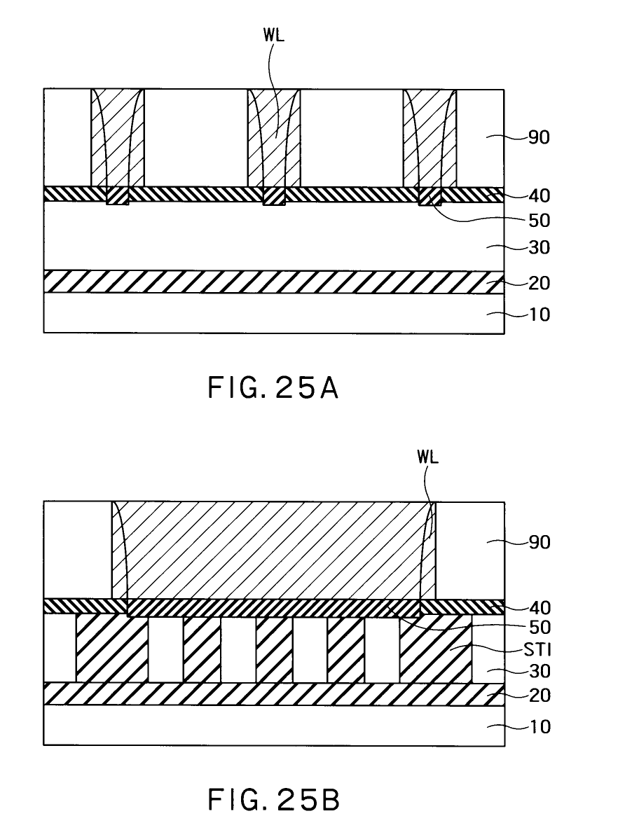

As shown in FIG. 24 to FIG. 25B, the second gate electrodes are filled into the formation regions of the word lines WL. In this case, a material of the second gate electrodes is the same as the material of the first gate electrodes. A set of the first gate electrode and the second gate electrode functions as one word line WL as one unit. Therefore, the first gate electrodes and the second gate electrodes are hereinafter collectively called word lines WL. FIG. 25A is a cross-sectional view along a line A-A in FIG. 24. FIG. 25B is a cross-sectional view along a line B-B in FIG. 24.

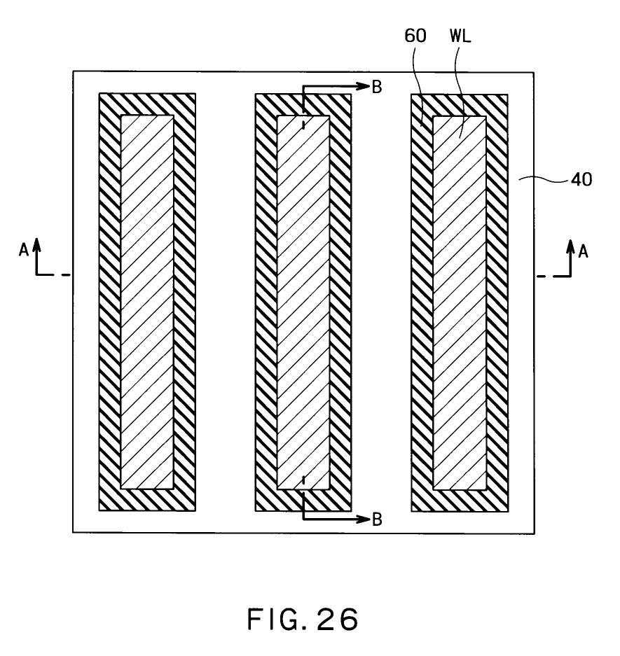

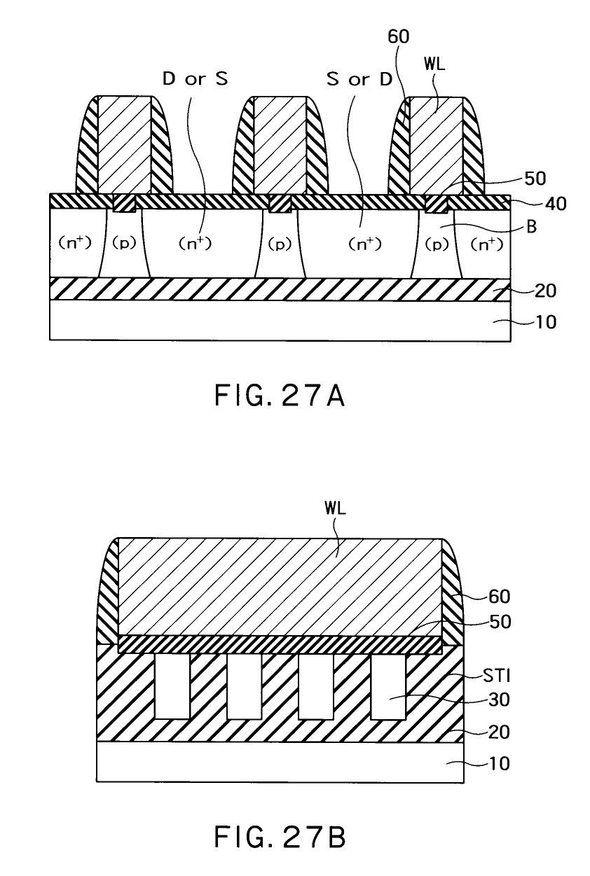

Next, as shown in FIG. 26 to FIG. 27B, the mask material 90 is removed, and thereafter, the sidewall film 60 is formed on the side surface of the word lines WL. An n-type impurity is introduced into the SOI layer 30 by using the word lines WL and the sidewall film 60 as a mask. Further, by heat processing, an n⁺ diffusion layer is formed in self alignment. This diffusion layer becomes the source S or the drain D. According to need, an n-type extension layer (not shown) can be formed around the source S or the drain D. The SOI layer 30 between the source S and the drain D becomes the body B. FIG. 27A is a cross-sectional view along a line A-A in FIG. 26. FIG. 27B is a cross-sectional view along a line B-B in FIG. 26.

The boundary gate dielectric film 40 is formed on an offset portion from an end of each word line WL to a boundary between the body and the source, and on an offset portion from an end of each word line WL to a boundary between the body and the drain. The center gate dielectric film 50 is provided adjacently to the boundary gate dielectric film 40 on the body B.

When the first gate electrodes G1 (WL1) are nitrided, in the process shown in FIG. 25A, an upper part of the word lines WL is polished by using CMP (Chemical Mechanical Polishing). Accordingly, the first gate electrodes G1 (WL1) appear on an upper surface of the word lines WL. Consequently, a contact (not shown) of the word lines WL can be contacted to both the first and second gate electrodes. As a result, in the process shown in FIG. 23A, there is no problem even when a nitride film is formed on the surface of the first gate electrodes G1 (WL1).

### Third Embodiment

A third embodiment of the present invention is different from the first embodiment in a manufacturing method, while the configuration of an FBC memory according to the third embodiment can be the same as that of the first embodiment. A method of manufacturing the FBC memory according to the third embodiment is explained below.

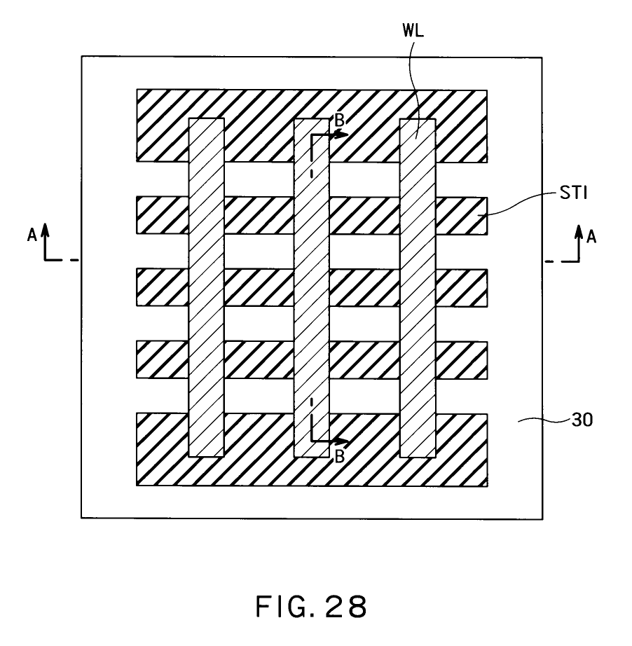

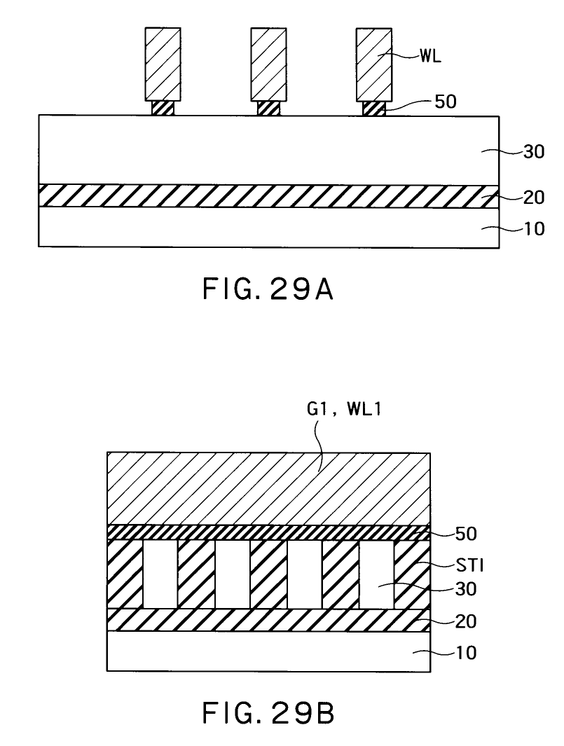

After the process in FIG. 5 to FIG. 8B, the center gate dielectric film 50 is etched by using gate electrodes G (word lines WL) as a mask, as shown in FIGS. 28 to 29B. Further, etching is performed anisotropically to narrow a width of the center gate dielectric film 50 in a column direction. As a result, the center gate dielectric film 50 having a width smaller than the width F of the gate electrodes G (WL) is formed. In the third embodiment, the word lines WL are not separated by the first and second gate electrodes.

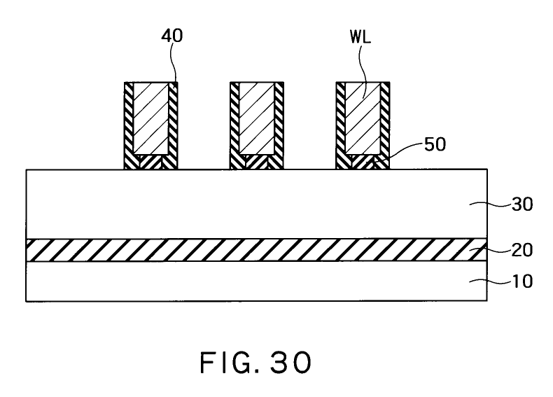

A material of the boundary gate dielectric film 40 is then formed on the surface of the gate electrodes G (WL) and the SOI layer 30. Further, the material of the boundary gate dielectric film 40 is etched back. As a result, as shown in FIG. 30, the boundary gate dielectric film 40 is formed adjacently to the center gate dielectric film 50 below the gate electrodes G (WL). The material of the boundary gate dielectric film 40 and the center gate dielectric film 50 in the third embodiment can be the same as that of the first embodiment.

Thereafter, similarly to the first and second embodiments, the sidewall film 60 is formed on the side surface of the word lines WL. An n-type impurity is introduced into the SOI layer 30 by using the word lines WL and the sidewall film 60 as a mask, thereby forming the source S and the drain D. Thereafter, an interlayer dielectric film is deposited on the whole surface, and the source line contact SLC, the bit line contact BLC, the source lines SL, and the bit lines BL are formed, thereby completing the FBC memory according to the third embodiment.

1. A semiconductor memory device comprising:
a supporting substrate;
an insulation film provided on the supporting substrate;
a source layer provided on the insulation film;
a drain layer provided on the insulation film;
a body region provided between the source layer and the drain layer and being in an electrically floating state, the body region accumulating electric charges or discharging electric charges in order to store data;
a boundary gate dielectric film provided at least on a boundary portion between the body region and the source layer and on a boundary portion between the body region and the drain layer; and
a center gate dielectric film provided adjacently to the boundary gate dielectric film on the body region, the center gate dielectric film having more interface states than the boundary gate dielectric film has.

2. A semiconductor memory device comprising:
a supporting substrate;
an insulation film provided on the supporting substrate;
a source layer provided on the insulation film;
a drain layer provided on the insulation film;
a body region provided between the source layer and the drain layer and being in an electrically floating state, the body region accumulating electric charges or discharging electric charges in order to store data;
a boundary gate dielectric film provided at least on a boundary portion between the body region and the source layer and on a boundary portion between the body region and the drain layer, the boundary gate dielectric film having an interface state density lower than 10¹¹eV⁻¹cm⁻²; and
a center gate dielectric film provided adjacently to the boundary gate dielectric film on the body region, the center gate dielectric film having an interface state density equal to or higher than 10¹¹eV⁻¹cm⁻².

3. The device of claim 1, wherein
in performing a refresh operation of restoring the data from deterioration thereof,
number of electric charges injected into the body region is larger than number of electric charges discharged from the body region when a potential in the body region is larger than a certain critical value, and
number of electric charges injected into the body region is smaller than number of electric charges discharged from the body region when a potential in the body region is smaller than the critical value.

4. The device of claim 2, wherein
in performing a refresh operation of restoring the data from deterioration thereof,
number of electric charges injected into the body region is larger than number of electric charges discharged from the body region when a potential in the body region is larger than a certain critical value, and
number of electric charges injected into the body region is smaller than number of electric charges discharged from the body region when a potential in the body region is smaller than the critical value.

5. The device of claim 3, wherein
in performing a refresh operation of restoring the data from deterioration thereof,
electric charges injected into the body region are generated by an impact ionization current,
electric charges discharged from the body region are extinguished from the body region by a charge pumping current, and
a quantity of electric charges injected into the body region based on the impact ionization current flowing within one cycle of the refresh operation and a quantity of electric charges discharged from the body region based on the charge pumping current flowing within one period of the refresh operation shift to a stationary state in which both quantities become substantially equal.

6. The device of claim 4, wherein
in performing a refresh operation of restoring the data from deterioration thereof,
electric charges injected into the body region are generated by an impact ionization current,
electric charges discharged from the body region are extinguished from the body region by a charge pumping current, and
a quantity of electric charges injected into the body region based on the impact ionization current flowing within one cycle of the refresh operation and a quantity of electric charges discharged from the body region based on the charge pumping current flowing within one period of the refresh operation shift to a stationary state in which both quantities become substantially equal.

7. The device of claim 3, wherein
in performing a refresh operation of restoring the data from deterioration thereof,
electric charges discharged from the body region are extinguished from the body region by being combined with electric charges trapped in interface states of the boundary gate dielectric film and the center gate dielectric film.

8. The device of claim 4, wherein
in performing a refresh operation of restoring the data from deterioration thereof,
electric charges discharged from the body region are extinguished from the body region by being combined with electric charges trapped in interface states of the boundary gate dielectric film and the center gate dielectric film.

9. A method of manufacturing a semiconductor memory device comprising as memory cells a plurality of FETs comprising a body region provided between a source layer and a drain layer and in an electrically floating state to accumulate electric charges or to discharge electric charges in order to store data, the method comprising:
forming a center gate dielectric film on a semiconductor layer provided on an insulation film;
forming first gate electrodes on the center gate dielectric film;
etching a side surface of the first gate electrodes in order to narrow a width of the first gate electrodes in a channel length direction of the memory cells;
etching the center gate dielectric film by using the first gate electrodes as a mask;
forming a boundary gate dielectric film on the semiconductor layer exposed;
forming second gate electrodes on a side wall of the first gate electrodes; and
forming the source layer and the drain layer by introducing an impurity into the semiconductor layer by using the first gate electrodes and the second gate electrodes as a mask, wherein
the boundary gate dielectric film is on a boundary portion between the body region and the source layer and on a boundary portion between the body region and the drain layer, and
the center gate dielectric film is provided adjacently to the boundary gate dielectric film on the body region.

10. The method of claim 9, wherein the center gate dielectric film has more interface states than those of the boundary gate dielectric film.

11. The method of claim 10, wherein
the boundary gate dielectric film is an insulation film having an interface state density lower than 10¹¹eV⁻¹cm⁻², and
the center gate dielectric film is an insulation film having an interface state density equal to or higher than 10¹¹eV⁻¹cm⁻².

12. A method of manufacturing a semiconductor memory device comprising as memory cells a plurality of FETs comprising a body region provided between a source layer and a drain layer and in an electrically floating state to accumulate electric charges or to discharge electric charges in order to store data, the method comprising:
forming a boundary gate dielectric film on a semiconductor layer provided on an insulation film;
forming a mask material on the boundary gate dielectric film;
removing a part of the mask material on a forming region of a gate electrode of the FET to expose the boundary gate dielectric film;
forming first gate electrodes on side surfaces of the mask material in the forming region of the gate electrode;
forming a center gate dielectric film by nitriding the boundary gate dielectric film using the mask material and the first gate electrodes as a mask;
filling the forming region of the gate electrode of the FET with a material of a second gate electrode;
removing the mask material; and
forming the source layer and the drain layer by introducing an impurity into the semiconductor layer by using the first gate electrodes and the second gate electrodes as a mask, wherein
the boundary gate dielectric film is on a boundary portion between the body region and the source layer and on a boundary portion between the body region and the drain layer, and
the center gate dielectric film is provided adjacently to the boundary gate dielectric film on the body region.

13. The method of claim 12, wherein the center gate dielectric film has more interface states than those of the boundary gate dielectric film.

14. The method of claim 13, wherein
the boundary gate dielectric film is an insulation film having an interface state density lower than 10¹¹eV⁻¹cm⁻², and
the center gate dielectric film is an insulation film having an interface state density equal to or higher than 10¹¹eV⁻¹cm⁻².

15. A method of manufacturing a semiconductor memory device comprising as memory cells a plurality of FETs comprising a body region provided between a source layer and a drain layer and in an electrically floating state to accumulate electric charges in order to store data or to discharge electric charges, the method comprising:
forming a center gate dielectric film on a semiconductor layer provided on an insulation film;
forming gate electrodes on the center gate dielectric film;
etching the center gate dielectric film by using the gate electrodes as a mask in order to narrow a width of the center gate dielectric film in a channel length direction of the FETs;
forming a boundary gate dielectric film so as to be adjacent to the center gate dielectric film below the gate electrodes; and
forming the source layer and the drain layer by introducing an impurity into the semiconductor layer by using the gate electrodes as a mask, wherein
the boundary gate dielectric film is on a boundary portion between the body region and the source layer and on a boundary portion between the body region and the drain layer, and
the center gate dielectric film is provided adjacently to the boundary gate dielectric film on the body region.

16. The method of claim 15, wherein the center gate dielectric film has more interface states than those of the boundary gate dielectric film.

17. The method of claim 16, wherein
the boundary gate dielectric film is an insulation film having an interface state density lower than 10¹¹eV⁻¹cm⁻², and
the center gate dielectric film is an insulation film having an interface state density equal to or higher than 10¹¹eV⁻¹ cm⁻².
